(19) United States
(12) Patent Application Publication
(10) Pub. No.: US 2024/0427062 A1
(43) Pub. Date: Dec. 26, 2024

(54) MICRO-STRUCTURE FILM AND LIGHT EMITTING MODULE

(71) Applicant: Darwin Precisions Corporation, Hsinchu County (TW)

(72) Inventors: YU-CHENG CHANG, Hsinchu County (TW); Wen-Tai Shen, Hsinchu County (TW); Yu-Ming Huang, Hsinchu County (TW)

(21) Appl. No.: 18/651,722

(22) Filed: May 1, 2024

(30) Foreign Application Priority Data
Jun. 21, 2023 (TW) 112123317

(51) Int. Cl. G02B 5/02

(52) U.S. Cl. CPC G02B 5/0215; G02B 5/0278

(57) ABSTRACT

A micro-structure film and a light emitting module are disclosed. A plurality of micro-structures with at least one predefined shape are uniformly distributed on at least one of surfaces of two opposite sides of the micro-structure film. The light emitting module includes a substrate, a plurality of light sources, and a package layer. The substrate has a first surface. The plurality of light sources are arranged on the first surface. The package layer is arranged on the first surface to contact with and cover the light sources. A plurality of micro-structures with at least one predefined shape are uniformly distributed on an other side of the package layer opposite to the first surface.

### CROSS-REFERENCE TO RELATED APPLICATION

This application claims the priority benefit of Taiwan application serial no. 112123317 filed on Jun. 21, 2023. The entirety of the above-mentioned patent applications is hereby incorporated by reference herein and made a part of this specification.

### TECHNICAL FIELD

The present invention relates to a micro-structure film and a light emitting module, and specifically, to a micro-structure film used with a light source, and an LED array light emitting module having a micro-structure package layer.

### BACKGROUND

In a conventional light emitting module, point light sources of a light emitting diode are arranged in an array manner to form a surface light source, and mostly a diffusion plate or an optical film is stacked to homogenize light, to reduce a situation in which point light sources of light emitting diodes are directly observed, that is, a so-called mura phenomenon. However, use of the diffusion plate or another optical film generally increase a thickness of a module. If the thickness needs to be reduced, a quantity of point light sources of the light emitting diode may be increased. However, costs are correspondingly increased. Therefore, there is space for improving the conventional light emitting module.

### SUMMARY

An objective of the present invention is to provide a micro-structure film and a light emitting module, so that a quantity of used various optical films can be reduced, and optical efficiency can also be improved.

Another objective of the present invention is to provide a micro-structure film and a light emitting module, so that a quantity of used light sources can be reduced, and optical efficiency can also be improved.

A micro-structure film of the present invention includes a light-incident surface and a light-exit surface located on two opposite sides, where a plurality of micro-structures are uniformly distributed on at least one of the light-incident surface and the light-exit surface. The micro-structure is convex or concave from the light-incident surface or the light-exit surface, and a vertical projection of the micro-structure on the light-incident surface is provided with a projection long axis, a base surface, and a central curve, where the central curve may be a circle, an ellipse, or a parabola. A periphery of the base surface is provided with two end corners located on opposite sides and respectively connected to two ends of the projection long axis, a vertical distance of the central curve relative to the base surface is maximum at a center point of the central curve, and a first arc edge and a second arc edge are respectively formed on a periphery of the base surface other than the two end corners relative to the central curve. For a plane that is perpendicular to the light-incident surface and parallel to the central curve and that passes through the center point of the central curve, a triangular central section is defined among intersections of the plane with the first arc edge and the second arc edge, and the center point of the central curve, and the central section has a first angle and a second angle at the intersections of the central section with the first arc edge and the second arc edge.

A light emitting module of the present invention includes a substrate, a plurality of light sources, a package layer, and a micro-structure film. The substrate has a first surface. The plurality of light sources are arranged on the first surface. The package layer is arranged on the first surface to contact with and cover the light sources. The micro-structure film is arranged on an other side of the package layer opposite to the first surface, and a plurality of micro-structures are uniformly distributed on an other surface of the micro-structure film opposite to the package layer. The micro-structure is concave toward the first surface or convex away from the first surface, and a vertical projection of the micro-structure on the first surface is provided with a projection long axis, a base surface, and a central curve, where the central curve may be a circle, an ellipse, or a parabola. A periphery of the base surface is provided with two end corners located on opposite sides and respectively connected to two ends of the projection long axis, a vertical distance of the central curve relative to the base surface is maximum at a center point of the central curve, and a first arc edge and a second arc edge are respectively formed on a periphery of the base surface other than the two end corners relative to the central curve. For a plane that is perpendicular to the first surface and parallel to the central curve and that passes through the center point of the central curve, a triangular central section is defined among intersections of the plane with the first arc edge and the second arc edge, and the center point of the central curve, and the central section has a first angle and a second angle at the intersections of the central section with the first arc edge and the second arc edge.

### BRIEF DESCRIPTION OF THE DRAWINGS

FIG. 1A is a schematic diagram of an embodiment of a light emitting module according to the present invention;

FIG. 1B is a schematic diagram of a different embodiment of a light emitting module according to the present invention;

FIG. 2A to FIG. 2E are schematic diagrams of an embodiment of a micro-structure in a light emitting module according to the present invention;

FIG. 3A to FIG. 5B are schematic diagrams of an embodiment of a micro-structure formed by a plurality of V-shaped cut grooves in a light emitting module according to the present invention;

FIG. 6A and FIG. 6B are schematic diagrams of a different embodiment of a micro-structure having a structure of a curved surface in a light emitting module according to the present invention;

FIG. 7A shows a simulation test result of an embodiment of a light emitting module according to the present invention;

FIG. 7B shows a simulation test result of a conventional light emitting module;

FIG. 7C shows a simulation test result of a different embodiment of a light emitting module according to the present invention;

FIG. 7D shows another simulation test result of a conventional light emitting module; and

FIG. 8A to FIG. 8C are schematic diagrams of a different embodiment of a light emitting module according to the present invention.

### DETAILED DESCRIPTION

Implementations of a connection assembly disclosed in the present invention are described below by using specific embodiments and referring to drawings, and a person skilled in the art may understand advantages and effects of the present invention from content disclosed in the present specification. However, the content disclosed below is not intended to limit the scope of protection of the present invention, and a person skilled in the art may implement, without departing from the spirit of the present invention, the present invention in another different embodiment based on a different viewpoint and an application. In the accompanying drawings, thicknesses of a layer, a film, a panel, an area, and the like are exaggerated for clarity. Throughout the specification, a same reference numeral indicates a same element. It should be understood that, when an element such as a layer, a film, an area, or a substrate is referred to as being “on” or “connected to” another element, the element may be directly on or connected to the another element, or an intermediate element may exist. In contrast, when an element is referred to as being “directly on” or “directly connected to” another element, an intermediate element does not exist. As used herein, “connection” may refer to physical and/or electrical connection. Further, “electrically connection” or “coupling” may have another element between two elements.

It should be understood that, although terms such as “first”, “second”, and “third” may be used herein for describing various elements, components, areas, layers, and/or sections, the elements, components, areas, and/or sections should not be limited by the terms. The terms are merely used for distinguishing an element, a component, an area, a layer, or a section from another element, component, area, layer, or section. Therefore, a “first element”, a “component”, an “area”, a “layer”, or a “section” discussed below may be referred to as a second element, a component, an area, a layer, or a section without departing from guidance herein.

In addition, relative terms such as “lower” or “bottom” and “upper” or “top” may be used herein for describing a relationship between an element and another element, as shown in the figure. It should be understood that, the relative terms are intended to include a different orientation of a device different from an orientation shown in the figure. For example, if a device in an accompanying drawing is flipped, an element described as on a “lower” side of another element is oriented on an upper side of the another element. Therefore, an exemplary term “lower” may include “lower” and “upper” orientations, depending on a particular orientation of the accompanying drawing. Similarly, if a device in an accompanying drawing is flipped, an element described as “below” another element or a lower “element” is oriented above the another element. Therefore, an exemplary term “below” or “lower” may include above and below orientations.

“About”, “approximately”, or “substantially” used herein include a stated value and an average value within an acceptable deviation range determined by a person of ordinary skill in the art, and measurement in question and a specific quantity of measurement-related errors (that is, a limitation of a measurement system) are taken into account. For example, “about” may indicate to be within one or more standard deviations of the stated value, or within +30%, +20%, +10%, or +5%. Further, “about”, “approximately”, or “substantially” used herein may select an acceptable deviation range or standard deviation based on an optical property, an etching property, or another property, without using a standard deviation suitable for all properties.

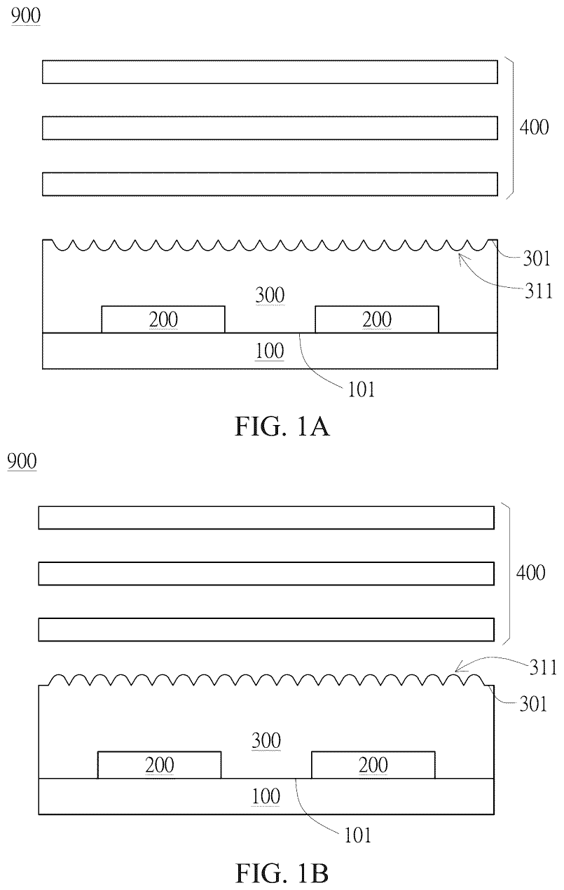

In an embodiment shown in FIG. 1A, a light emitting module 900 of the present invention includes a substrate 100, a plurality of light sources 200, and a package layer 300. The substrate 100 has a first surface 101. The plurality of light sources 200 are arranged on the first surface 101. The package layer 300 is arranged on the first surface 101 to contact with and cover the light sources 200. Further, the substrate 100 includes a printed circuit board, and the light sources 200 are preferably light emitting diode (LED) light sources or sub-millimeter light emitting diode (Mini LED) light sources. The light sources 200 are arranged on the first surface 101 of the substrate 100 in a chip on board manner and form an array. The package layer 300 covers the first surface 101 and the light sources 200, and is filled between the light sources 200. The light emitting module 900 may further include an optical film 400, arranged above the package layer 300. The optical film 400 may include a diffusion plate, or another film or plate-like element that modulates an optical behavior.

The package layer 300 may be, for example, transparent, translucent, or fluorescent, and may be mixed with a wavelength conversion material, for example, a phosphorescent substance. The package layer 300 may be made of silicon resin, epoxy resin, glass, plastic, or another material, and may be directly formed on the first surface 101 and the light sources 200 by using an injection molding technology.

In the embodiment shown in FIG. 1A, a plurality of micro-structures 311 are uniformly distributed on an other side 301 of the package layer 300 opposite to the first surface 101. In other words, the package layer 300 opposite to the first surface 101 is provided with the micro-structures 311 concave toward the first surface 101 and uniformly distributed. When the package layer 300 is formed by using the injection molding technology, the micro-structures 311 may be formed simultaneously, or may be formed after the package layer 300 are formed. For example, a material same as that of the package layer 300 is deposited by using a chemical vapor deposition method, or a part of the package layer 300 is removed in a manner of etching, mechanical processing, transfer printing, sandblasting, or the like. In a different embodiment shown in FIG. 1B, the package layer 300 opposite to the first surface 101 is provided with the micro-structures 311 convex away from the first surface 101 and uniformly distributed.

Materials on two sides of the micro-structures 311 have different refractivity, in other words, a value of N is different. In other words, refractivity of the package layer 300 is different from refractivity of a material on the other side of the package layer 300 opposite to the substrate 100. Specifically, in an embodiment, there is air on the other side of the package layer 300 opposite to the substrate 100. In other words, the air is filled between the micro-structures 311 toward the optical film 400. In a different embodiment, the other side of the package layer 300 opposite to the substrate 100 may be provided with a layer formed by different substances, and the different substances are filled between the micro-structures 311 toward the optical film 400.

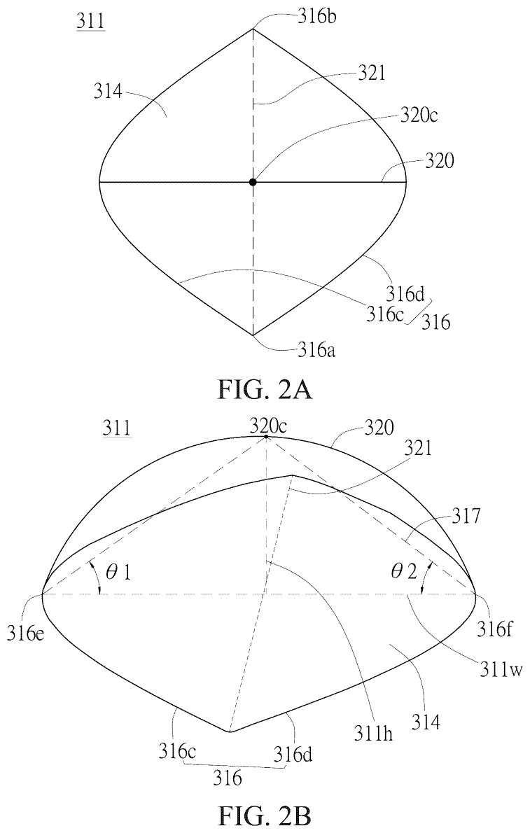

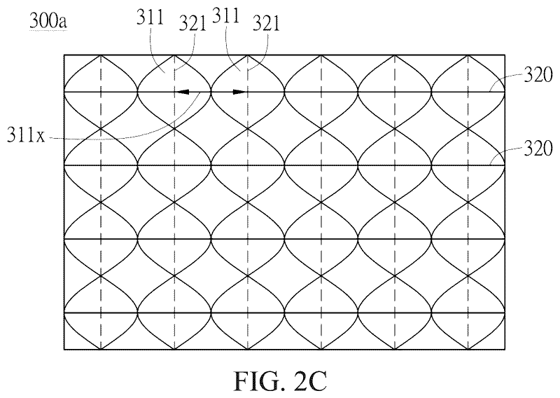

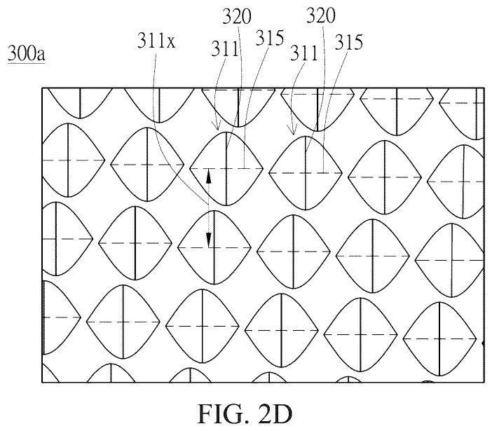

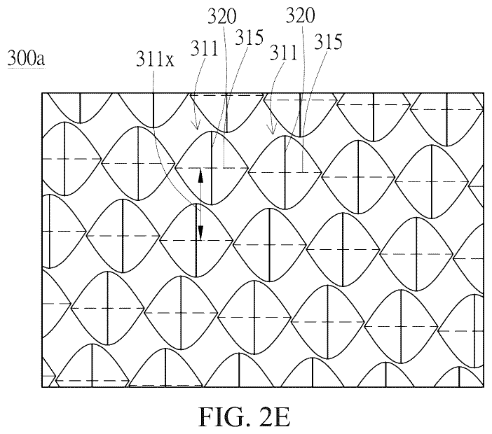

In an embodiment shown in FIG. 2A to FIG. 2C, FIG. 2A and FIG. 2B are respectively a three-dimensional view and a top view of a unit of a micro-structure 311, and FIG. 2C is a top view of the plurality of micro-structures 311. As shown in FIG. 2A, in an embodiment, a vertical projection of a micro-structure 311 on the first surface 101 (referring to FIG. 1A and FIG. 1B) is provided with a projection long axis 321, a base surface 314, and a central curve 320. The base surface 314 is a plane surrounded by edges of the micro-structure 311. The central curve 320 may be a circle, an ellipse, or a parabola. A periphery of the base surface 314 is provided with two end corners 316a and 316b located on opposite sides and respectively connected to two ends of the projection long axis 321, a vertical distance 311h of the central curve 320 relative to the base surface 314 is maximum at a center point 320c of the central curve, and a first arc edge 316c and a second arc edge 316d are respectively formed on a periphery of the base surface 314 other than the two end corners 316a and 316b relative to the central curve 320. For a plane that is perpendicular to the first surface 101 and parallel to the central curve 320 and that passes through the center point 320c of the central curve 320, a triangular central section 317 is defined among intersections 316e and 316f of the plane with the first arc edge 316c and the second arc edge 316d, and the center point 320c of the central curve 320, and the central section 317 has a first angle θ1 and a second angle θ2 at the intersections of the central section with the first arc edge 316c and the second arc edge 316d.

Observed from a different angle, the micro-structure 311 has a U-shaped hull-like appearance, the first arc edge 316c and the second arc edge 316d jointly form a periphery 316 of the base surface 314 and are connected at the end corners 316a and 316b, and the central section 317 is a section tangent to the center point 320c, namely, a highest point, of the central curve 320 relative to the base surface 314. In an embodiment, the first angle ranges from 20° to 40°, and the second angle ranges from 20° to 40°. A micro-structure width 311w is provided on the base surface 314 between the intersection 316e of the first arc edge 316c and the central section 317 and the intersection 316f of the second arc edge 316d and the central section 317, and the micro-structure width 311w ranges from 50 μm to 200 μm. The vertical distance 311h of the central curve 320 relative to the base surface 314 ranges from 5 μm to 30 μm at the center point 320c of the central curve 320. In other words, a height/depth of the micro-structure 311 ranges from 5 μm to 30 μm. In an embodiment shown in FIG. 2C, a distance between projection long axes 321 of two adjacent micro-structures 311 is a pitch 311x, and the pitch 311x ranges from 50 μm to 300 μm. In addition, in an embodiment shown in FIG. 2D and FIG. 2E, an arrangement of the micro-structures 311 is not limited to linear alignment, and may be adjusted to achieve a good light uniformity effect overall.

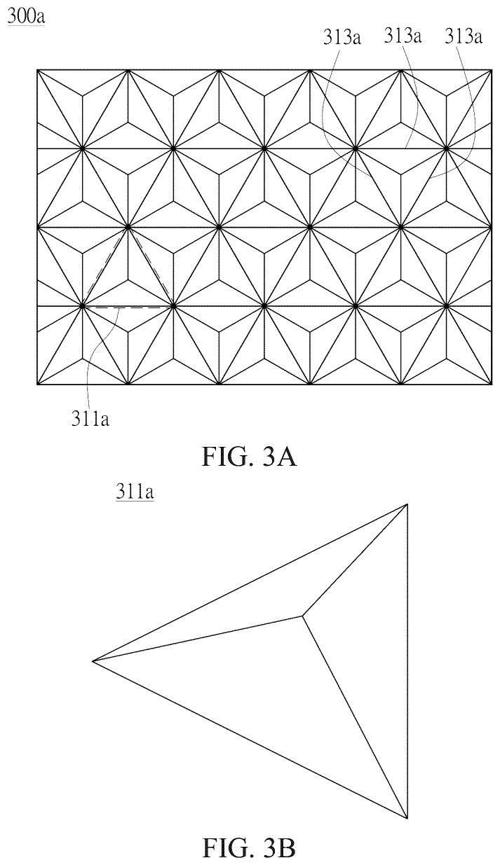

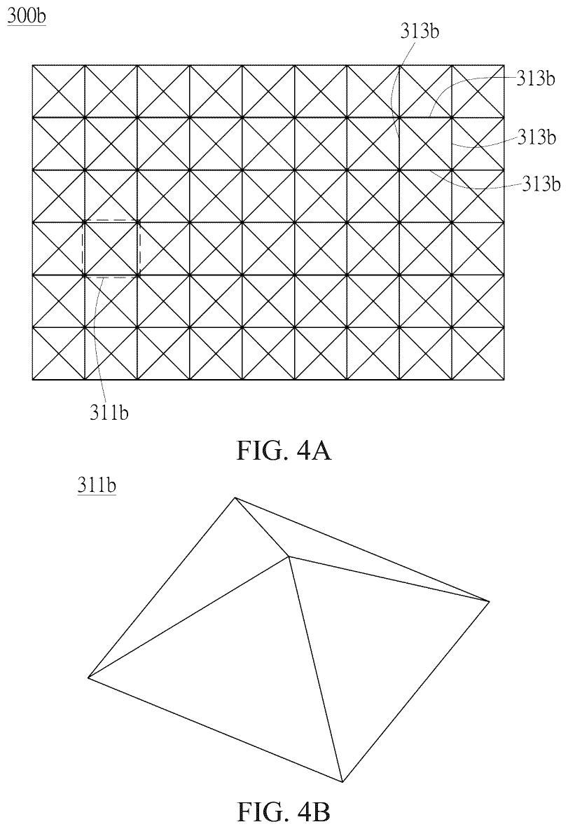

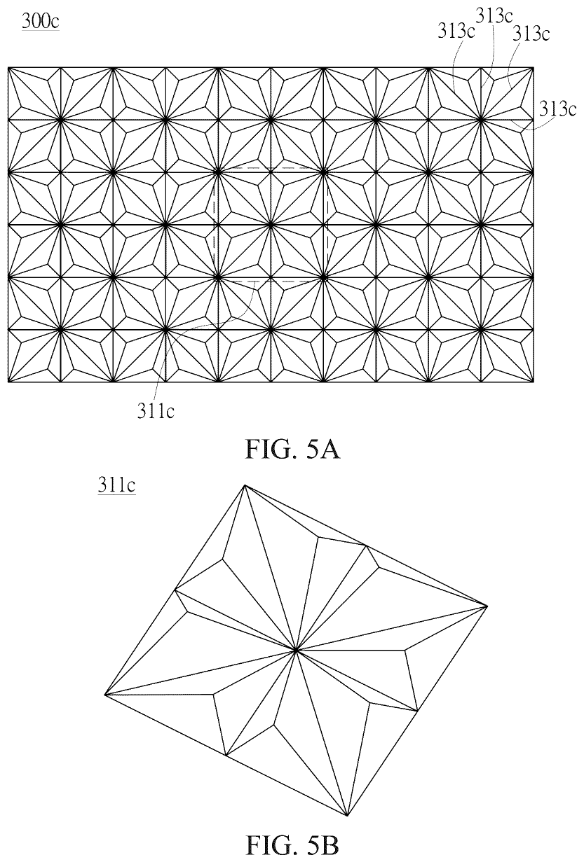

A size and a shape of the micro-structure 311 may vary depending on use, manufacturing, or another consideration. For example, in embodiments shown in FIG. 3A, FIG. 4A, and FIG. 5A, the micro-structure 311 is formed by a plurality of V-shaped cut grooves, and an angle of each V-shaped groove is θ, where 30°θ≤150°. More specifically, in an embodiment shown in FIG. 3A, a micro-structure 311a is formed by three groups of V-shaped cut grooves 313a, and an angle between adjacent V-shaped cut grooves 313a is 45°. In an embodiment shown in FIG. 3B, the micro-structure 311a is of a triangular pyramid shape. In other words, in this embodiment, a predefined shape of the micro-structure 311a is the triangular pyramid shape. Further, during actual production, a V-shaped cut groove 313a may be directly engraved on a surface of the package layer 300 by using a tool, to form the micro-structure 311a. Alternatively, a corresponding shape of the V-shaped cut groove 313a may be first made on a mold, and then the V-shaped cut groove 313a and the micro-structure 311a may be formed on the surface of the package layer 300a in a hot pressing manner or another manner. The micro-structure 311 may be controlled to be concave toward the first surface 101 (referring to FIG. 1A) or convex away from the first surface 101 (referring to FIG. 1B) through a positive or a negative of the corresponding shape of the V-shaped cut groove 313a on the mold.

In embodiments shown in FIG. 4A and FIG. 4B, a micro-structure 311b is formed by two groups of V-shaped cut grooves 313b, and an angle between adjacent V-shaped cut grooves 313b is 90°. In an embodiment shown in FIG. 4B, the micro-structure 311b is of a quadrangular pyramid shape. In other words, in this embodiment, a predefined shape of the micro-structure 311b is the quadrangular pyramid shape. In embodiments shown in FIG. 5A and FIG. 5B, a micro-structure 311c is formed by four groups of V-shaped cut grooves 313c, and an angle between adjacent V-shaped cut grooves 313c is 45°. In an embodiment shown in FIG. 5B, the micro-structure 311c is of a four pointed star shape. In other words, in this embodiment, a predefined shape of the micro-structure 311c is the four pointed star shape.

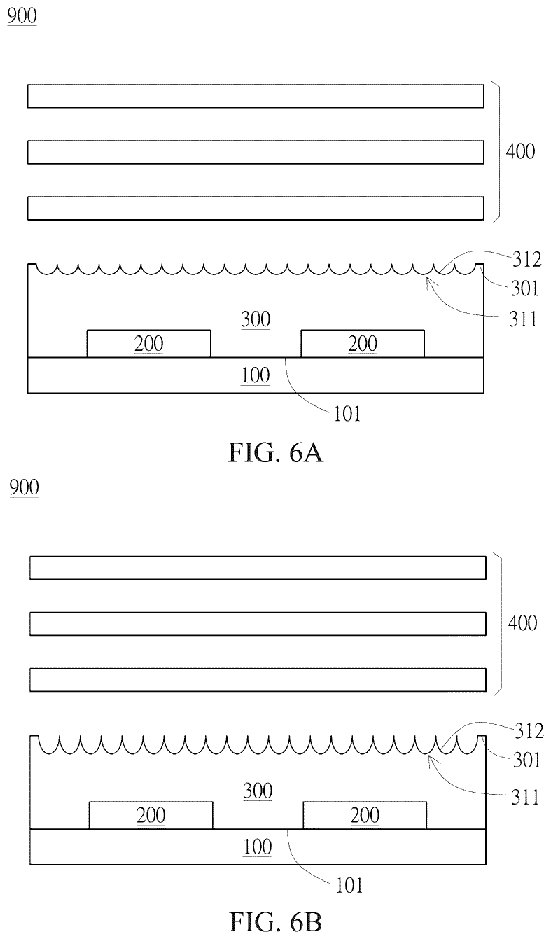

In embodiments shown in FIG. 6A and FIG. 6B, the micro-structure 311 have a structure of a curved surface 312. More specifically, the micro-structure 311 has a curved surface represented by the following Formula (1).

$$s ( x ) = \frac{{x}^{2}}{R + \sqrt{{R}^{2} - ( κ + 1 ) {x}^{2}}} \qquad Formula ( 1 )$$

s(x): a surface profile (sag profile).
x: a radial length of a vertical projection of each micro-structure on the substrate.
κ: conic constant.
r: a curvature radius.

Further, in an embodiment shown in FIG. 6A, the surface 301 of the package layer 300 is concave toward the substrate 100 to form the curved surface 312 having a semi-spherical inner surface feature. In other words, the micro-structure 311 substantially forms a hemispherical cavity, and a sharp corner may be formed at a junction of adjacent micro-structures 311. In a micro-structure, κ equals to 0, R ranges from 0.002 mm to 0.05 mm, a radius ranges from 5 μm to 500 μm, and a depth ranges from 10 μm to 200 μm. In an embodiment shown in FIG. 6B, the curved surface 312 of the micro-structure 311c is a semi-ellipsoid inner surface. Observed from a different angle, in this embodiment, the surface 301 of the package layer 300 is concave toward the substrate 100 to form the curved surface 312 having a semi-ellipsoid inner surface feature. In other words, the micro-structure 311 substantially forms a semi-ellipsoidal cavity. κ ranges from −1 to −2, R ranges from 0.002 mm to 0.05 mm, a radius ranges from 5 μm to 500 μm, and a depth ranges from 10 μm to 200 μm. The micro-structure 311 may be formed through chemical etching, mechanical machining, sandblasting, or the like.

Specifically, by arranging at least one micro-structure 311 with a predefined shape on the surface of the package layer 300 in the present invention, light emitted by the light sources 200 is dispersed, thereby reducing a need for using an optical film such as a diffusion plate, and improving optical efficiency, so that a quantity of the light sources 200 per unit area is reduced and a spacing between the light sources is increased. In different embodiments, the micro-structure 311 may have a different predefined shape, such as a U-shaped hull, a V-shaped hull, or a mixture of a hemisphere shape and a triangular pyramid shape, to enhance an effect of the micro-structure.

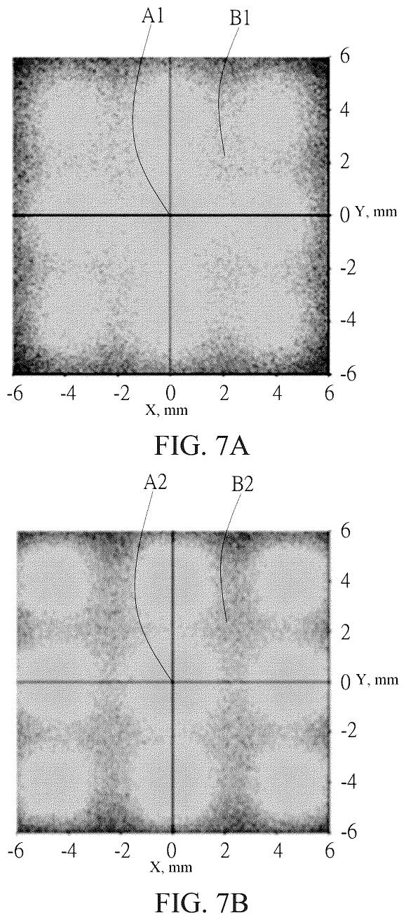

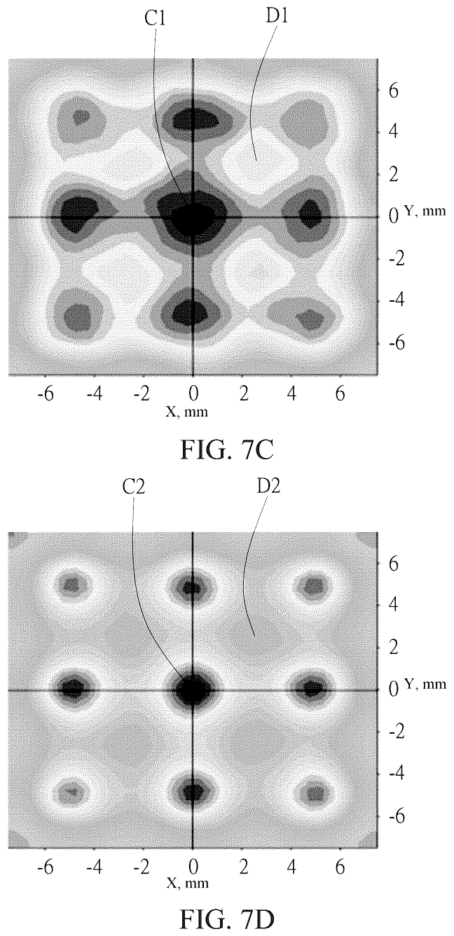

Further, software (LightTools, CYBERNET SYSTEMS TAIWAN, Taiwan) is used to perform simulation tests on the light emitting module of the present invention and a conventional light emitting module, where parameter settings are shown in Table 1. Simulation test results are shown in FIG. 7A and FIG. 7B respectively.

TABLE 1

| Light emitting module of the present invention | Conventional light emitting module |
|---|---|
| Light source: a Mini LED (model 0812, Lextar, | Light source: a Mini LED (model 0812, |
| Taiwan), with a spacing of 5 mm and a 4 × 4 array. | Lextar, Taiwan), with a spacing of 5 mm |
| Package layer: a thickness of 250 μm and | and a 4 × 4 array. |
| refractivity of 1.53, with a micro-structure and an | Package layer: a thickness of 250 μm and |
| arrangement pattern shown in FIG. 2A, FIG. 2B, | refractivity of 1.53, without a |
| and FIG. 2E. Parameters of the micro-structure: a | micro-structure. |
| first angle of 30°, a second angle of 30°, a | |
| micro-structure width of 90 μm, a micro-structure | |
| height of 25 μm, and a pitch of 97 μm. | |

In a simulation result shown in FIG. 7A, A1 is located directly above a light source, and B1 is located at a center directly above four adjacent light sources. A light intensity difference between A1 and B1 is small, and brightness uniformity is good. In a simulation result shown in FIG. 7B, A2 is located directly above a light source, and B2 is located at a center directly above four adjacent light sources. A light intensity difference between A2 and B2 is obvious, and brightness uniformity is poor. Therefore, it can be learned that in the light emitting module 900 of the present invention, even if use of the optical film such as the diffusion plate is reduced so that an overall thickness can be reduced, luminous uniformity is still good.

In another embodiment, the micro-structure is formed by three V-shaped cut grooves, where an angle of each V-shaped cut groove is 80°, and a depth of structure machining is 30 μm. In a simulation result shown in FIG. 7C, C1 is located directly above a light source, and D1 is located at a center directly above four adjacent light sources. A light intensity difference between C1 and D1 is small, and brightness uniformity is good. In a simulation result shown in FIG. 7D, C2 is located directly above a light source, and D2 is located at a center directly above four adjacent light sources. A light intensity difference between C2 and D2 is obvious, and brightness uniformity is poor. Specifically, compared with FIG. 7D, image uniformity of FIG. 7C may be improved from 14% to 52%. Therefore, the micro-structure may further achieve good brightness uniformity.

Optical measurement (Topcon SR-3AR, Japan) is further used, to measure center brightness and 13-point uniformity (10 mm from an edge), and test a 17.3-inch backlight unit using the conventional light emitting module and the light emitting module having the micro-structure of the specification shown in Table 1 respectively, where the micro-structure is arranged on the package layer, and a specification of the backlight unit is shown in Table 2 below.

TABLE 2

| | | Use the light emitting |
|---|---|---|
| | | module of the present |
| | Use the | invention (The |
| | conventional | micro-structure is |
| | light emitting | arranged on the |
| | module | package layer) |
| Quantity (ea) of Mini LEDs | 5760 | 3024 |
| Proportion of the quantity | 100% | 52.5% |
| Thickness (cm) of the | 2.49 | 2.18 |
| backlight unit | | |
| Center brightness (%) of the | 100% | 105% |
| light emitting module | | |
| Uniformity (%) of the light | 70% | 70% |
| emitting module | | |

From the results in the foregoing table, it can be obviously seen that, the quantity of Mini LEDs used in the light emitting module of the present invention is only 52.5% of that in the conventional light emitting module, and the thickness of the backlight unit is also effectively reduced, but the center brightness thereof is better and uniformity is the same. In other words, the light emitting module of the present invention has better optical efficiency and can reduce use of various optical films.

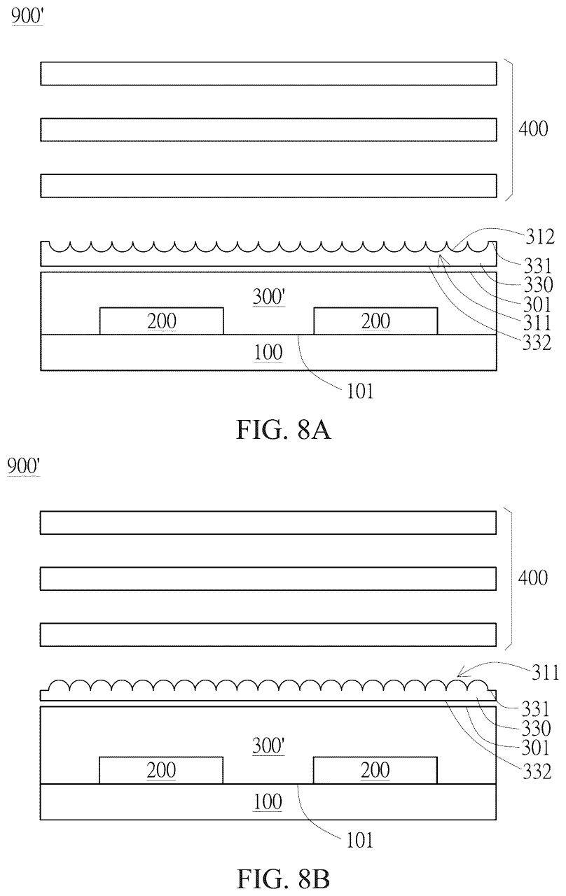

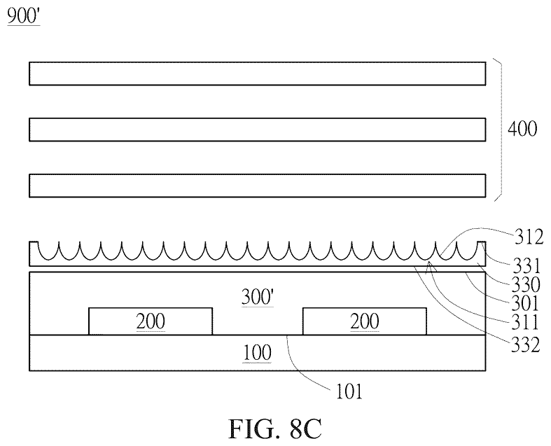

In an embodiment, the micro-structure is not limited to being arranged on the package layer; or the micro-structure may be arranged on an optical film to become a micro-structure film, and the micro-structure film is arranged on the package layer. In other words, a plurality of micro-structures with at least one predefined shape are uniformly distributed on at least one of surfaces of two opposite sides of the micro-structure film. More specifically, in a different embodiment shown in FIG. 8A to FIG. 8C, a light emitting module 900′ includes a substrate 100, a plurality of light sources 200, a package layer 300′, and a micro-structure film 330. The substrate 100 has a first surface 101. The plurality of light sources 200 are arranged on the first surface 101. The package layer 300′ is arranged on the first surface 101 to contact with and cover the light sources 200. The micro-structure film 330 is arranged on an other side of the package layer 300′ opposite to the first surface 101, and a plurality of micro-structures 311 with at least one predefined shape are uniformly distributed on an other surface 331 of the micro-structure film 330 opposite to the package layer 300′. Light emitted by the light sources 200 enters and exits the micro-structure 311 through a surface 332 and the surface 331 respectively. In other words, the surface 332 and the surface 331 are respectively a light-exit surface and a light-incident surface of the micro-structure 311. A vertical projection of the micro-structure 311 on the surface 331 (referring to FIG. 2A and FIG. 2B) is provided with a projection long axis 321, a base surface 314, and a central curve 320. The micro-structure film 330 may be made of a same material as or a different material from the package layer 300′. Further, the micro-structure film 330 with the micro-structure 311 and the package layer 300′ may be separately manufactured in different processes, and then the micro-structure film 330 is arranged on the package layer 300′. In addition, in a different embodiment, the micro-structure film 330 may be arranged on a different position in a light emitting module based on manufacturing, a design or use requirement, for example, arranged between other optical films or arranged on an other side opposite to the package layer; or may be used in combination with another optical device, for example, arranged on a surface of a light source or arranged on an outer side of a display surface of a monitor. In the micro-structure film 330, x in Formula (1) is a radial length of the vertical projection of the micro-structure on the surface of the micro-structure film.

Optical measurement (Topcon SR-3AR, Japan) is further used, to measure center brightness and 13-point uniformity (10 mm from an edge), and test a 17.3-inch backlight unit using the conventional light emitting module and the light emitting module having the micro-structure of the specification shown in Table 1 respectively, where the structure is arranged on an optical film, and a specification of the backlight unit is shown in Table 3 below.

TABLE 3

| | | Use the light emitting |
|---|---|---|
| | | module of the present |
| | Use the | invention (The |
| | conventional | micro-structure is |
| | light emitting | arranged on the |
| | module | micro-structure film) |
| Quantity (ea) of Mini LEDs | 5760 | 3024 |
| Proportion of the quantity | 100% | 52.5% |
| Thickness (cm) of the | 2.49 | 2.10 |
| backlight unit | | |
| Center brightness (%) of the | 100% | 103% |
| light emitting module | | |
| Uniformity (%) of the light | 70% | 70% |
| emitting module | | |

From the results in the foregoing table, it can be obviously seen that, the quantity of Mini LEDs used in the light emitting module of the present invention with the micro-structure arranged on the micro-structure film is only 52.5% of that in the conventional light emitting module, and the thickness of the backlight unit is also effectively reduced, but the center brightness thereof is better and uniformity is the same. Observed from a different angle, the light emitting module using the micro-structure film also has better optical efficiency and can reduce use of various optical films.

The present invention has been described with reference to the foregoing related embodiments. However, the foregoing embodiments are merely examples for implementing the present invention. It needs to be pointed out that, embodiments disclosed do not limit the scope of the present invention. In contrast, modifications and equivalent arrangements included within the spirit and scope of the application patent scope are included in the scope of the present invention.

What is claimed is:

1. A micro-structure film, comprising a light-incident surface and a light-exit surface located on two opposite sides, wherein a plurality of micro-structures are uniformly distributed on at least one of the light-incident surface and the light-exit surface, each micro-structure is convex or concave from the light-incident surface or the light-exit surface, a vertical projection of the micro-structure on the light-incident surface is provided with a projection long axis, a base surface, and a central curve, a periphery of the base surface is provided with two end corners located on opposite sides and respectively connected to two ends of the projection long axis, a vertical distance of the central curve relative to the base surface is maximum at a center point of the central curve, and a first arc edge and a second arc edge are respectively formed on a periphery of the base surface other than the two end corners relative to the central curve, wherein for a plane that is perpendicular to the light-incident surface and parallel to the central curve and that passes through the center point of the central curve, a triangular central section is defined among intersections of the plane with the first arc edge and the second arc edge, and the center point of the central curve, and the central section has a first angle and a second angle at the intersections of the central section with the first arc edge and the second arc edge.

2. The micro-structure film according to claim 1, wherein the first angle ranges from 20° to 40°.

3. The micro-structure film according to claim 1, wherein the second angle ranges from 20° to 40°.

4. The micro-structure film according to claim 1, wherein a micro-structure width is provided on the base surface between an intersection of the first arc edge and the central section and an intersection of the second arc edge and the central section, and the micro-structure width ranges from 50 μm to 200 μm.

5. The micro-structure film according to claim 1, wherein the vertical distance of the central curve relative to the base surface ranges from 5 μm to 30 μm at the center point of the central curve.

6. The micro-structure film according to claim 1, wherein a distance between projection long axes of two adjacent micro-structures is a pitch, and the pitch ranges from 50 μm to 300 μm.

7. A light emitting module, comprising:
a substrate, having a first surface;
a plurality of light sources, arranged on the first surface;
a package layer, arranged on the first surface to contact with and cover the light sources; and
a micro-structure film, arranged on an other side of the package layer opposite to the first surface, wherein a plurality of micro-structures are uniformly distributed on an other surface of the micro-structure film opposite to the package layer, each micro-structure is concave toward the first surface or convex away from the first surface, a vertical projection of the micro-structure on the first surface is provided with a projection long axis, a base surface, and a central curve, a periphery of the base surface is provided with two end corners located on opposite sides and respectively connected to two ends of the projection long axis, a vertical distance of the central curve relative to the base surface is maximum at a center point of the central curve, and a first arc edge and a second arc edge are respectively formed on a periphery of the base surface other than the two end corners relative to the central curve, wherein for a plane that is perpendicular to the first surface and parallel to the central curve and that passes through the center point of the central curve, a triangular central section is defined among intersections of the plane with the first arc edge and the second arc edge, and the center point of the central curve, and the central section has a first angle and a second angle at the intersections of the central section with the first arc edge and the second arc edge.

8. The light emitting module according to claim 7, wherein the first angle ranges from 20° to 40°.

9. The light emitting module according to claim 7, wherein the second angle ranges from 20° to 40°.

10. The light emitting module according to claim 7, wherein a micro-structure width is provided on the base surface between an intersection of the first arc edge and the central section and an intersection of the second arc edge and the central section, and the micro-structure width ranges from 50 μm to 200 μm.

11. The light emitting module according to claim 7, wherein the vertical distance of the central curve relative to the base surface ranges from 5 μm to 30 μm at the center point of the central curve.

12. The light emitting module according to claim 7, wherein a distance between projection long axes of two adjacent micro-structures is a pitch, and the pitch ranges from 50 μm to 300 μm.

13. The light emitting module according to claim 7, wherein refractivity of the package layer is different from refractivity of a material on the other side of the package layer opposite to the substrate.
